(19) United States
(12) Patent Application Publication
(10) Pub. No.: US 2007/0018283 A1
(43) Pub. Date: Jan. 25, 2007

(54) ZENER DIODE

(75) Inventor: Hidenori Fujii, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Chiyoda-ku (JP)

(21) Appl. No.: 11/419,871

(22) Filed: May 23, 2006

(30) Foreign Application Priority Data
Jul. 19, 2005 (JP) 2005-208018

(51) Int. Cl. H01L 29/861

(52) U.S. Cl. 257/606

(57) ABSTRACT

A zener diode, including: a semiconductor substrate; a first region of the first conductivity type formed on the surface of the semiconductor substrate; and a second region of the second conductivity type formed on the surface of the semiconductor substrate and included in the first region; and having a pn junction between the first and the second regions. The concentration of the impurity of the first conductivity type in the first region is highest near the surface of the semiconductor substrate, and the concentration of the impurity of the second conductivity type in the second region is highest near the surface of the semiconductor substrate.

### CROSS-REFERENCE TO RELATED APPLICATION

The disclosure of Japanese Patent Application No. 2005-208018 filed on Jul. 19, 2005 including specification, drawings and claims is incorporated herein by reference in its entirety.

### BACKGROUND OF THE INVENTION

1. Field of the Invention

The present invention relates to a zener diode, and more particularly, to a zener diode having a gate electrode on a zener junction through a gate oxide film.

2. Description of the Related Art

FIG. 5 is a cross sectional view of a conventional zener diode generally denoted at 500 (JP, 03-87072, A). The zener diode 500 includes an n-type silicon substrate 51. A p-type well region 52 is formed in the silicon substrate 51. In the p-type well region 52, a p⁺ anode region 53 which is deeply injected, and an n⁺ cathode region which is injected to overlap with and to be shallower than the p⁺ anode region 53 are formed (The relation between the concentration and the depth of each region is shown on the right side of FIG. 5). A surface oxide film 55 is formed on the surface of the silicon substrate 51, and an insulating film 56 is formed on the surface oxide film 55. Furthermore, an anode electrode 57 is formed to be connected to the p-type well region 52, and a cathode electrode 58 is formed to be connected to the n⁺ cathode region 54.

### SUMMARY OF THE INVENTION

In the zener diode 500, a pn junction face of the diode is formed at the bottom surface of the n⁺ cathode region 54 which overlaps with the p⁺ anode region 53 (The symbol of the diode is indicated in FIG. 5). Zener voltage (breakdown voltage) is determined by concentrations of impurity in the p⁺ anode region 53 and n⁺ cathode region 54 which adjoin each other through the pn junction face.

It is difficult, however, to highly control the concentrations of the impurity near the pn junction surface, because the p⁺ anode region 53 and the n⁺ cathode region 54 are formed by using ion implantation or diffusion method. Hence, there arises a problem that the zener voltage of the each zener diode 500 is different from each other.

While, there also arises a problem of varying the zener voltage, when the p⁺ anode region 53 and the n⁺ cathode region 54 are formed as shallow regions. Because the pn junction (zener junction) is formed near the surface of the substrate 51, therefore, electrons formed by zener breakdown are trapped in the surface oxide film 55 (charge-up phenomenon).

An object of the present invention is to provide a zener diode having zener voltage which is highly controlled and does not vary.

The present invention is directed to a zener diode, including: a semiconductor substrate; a first region of the first conductivity type formed on the surface of the semiconductor substrate; and a second region of the second conductivity type formed on the surface of the semiconductor substrate and included in the first region; and having a pn junction between the first and the second regions. The concentration of the impurity of the first conductivity type in the first region is highest near the surface of the semiconductor substrate, and the concentration of the impurity of the second conductivity type in the second region is highest near the surface of the semiconductor substrate.

As clearly described above, according to the zener diode of the present invention, it is possible to control the value of the zener voltage with a high degree of accuracy.

### BRIEF DESCRIPTION OF THE DRAWINGS

FIG. 1 shows a cross sectional view of the zener diode according to the embodiment of the present invention;

FIG. 2 shows the relation between the gate voltage and the zener voltage according to the embodiment of the present invention;

FIG. 3 shows a control circuit of the zener diode according to the embodiment of the present invention;

FIGS. 4A-4D show cross sectional view of steps of producing the zener diode according to the embodiment of the present invention; and

FIG. 5 shows a cross sectional view of the conventional zener diode.

### DETAILED DESCRIPTION OF THE PREFERRED EMBODIMENTS

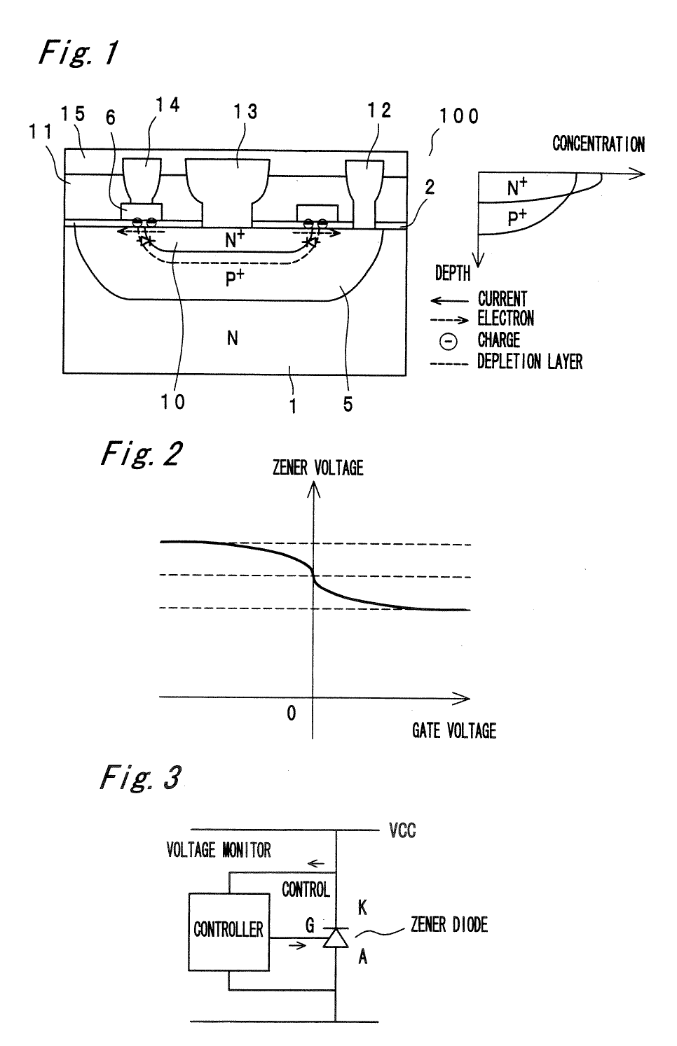

FIG. 1 is a cross sectional view of a zener diode according to the embodiment of the present invention, generally denoted at 100. The zener diode 100 includes an n-type silicon substrate 1. An n-type well region formed in a silicon substrate can be used as an n-type region.

A p⁺ anode region 5 is formed in the silicon substrate 1, and an n⁺ cathode region 10 is formed to be included in the p⁺ anode region S.

A surface silicon oxide film (gate oxide film) 2 is formed on the surface of the silicon substrate 1, and a gate electrode 6 of poly silicon for instance is formed on the surface silicon oxide film 2. Furthermore, a gate wiring 14 is formed on the gate electrode 6. On the other hand, an anode wiring 12 is connected to the p⁺ anode region 5 and a cathode wiring 13 is connected to the n⁺ cathode region 10, respectively.

The anode wiring 12, the cathode wiring 13, and gate wiring 14 are made of metal of aluminum for instance. The surface of the silicon substrate 1 is covered by an insulating film 11 of silicon oxide for instance, and a surface protecting film 15 of BPSG for instance.

As shown in a right figure of FIG. 1, in the zener diode 100, the concentration of the impurity in the p⁺ anode region 5 has a highest peak at the surface of the silicon substrate 1 as well as that in the n⁺ cathode region 10. Consequently, as shown with dashed line in FIG. 1, a depletion layer extended from the n⁺ cathode region 10 to the p anode region 5 has a certain thickness at the bottom of the n⁺ cathode region 10 and becomes thinner as approaching the surface of the silicon substrate 1.

In the zener diode 100, the zener voltage (breakdown voltage) is determined by the concentrations of the impurity of the p⁺ anode region 5 and the n⁺ cathode region 10. Because the zener breakdown tends to take place in the region having a thin depletion layer, namely in the region closed to the surface of the silicon substrate 1 (In FIG. 1, a symbol of the diode is shown in this region).

The concentrations of the impurity in the region closed to the surface of the silicon substrate 1 can be controlled with a high degree of accuracy, even when the impurity is injected or implanted into the silicon substrate 1 by using an ion implantation method or a diffusion method. In the zener diode 100 according to this embodiment, the zener voltage (breakdown voltage) is determined by the concentrations of the impurity in the regions close to the surface of the silicon substrate 1 as described above, the zener voltage can be controlled with a high degree of accuracy.

In the zener diode 100 according to this embodiment, the gate electrode 6 is formed on the zener junction (boundary between the p⁺ anode region 5 and the n⁺ cathode region 10) in the silicon substrate 1 through the surface silicon oxide film 2. The voltage of the gate electrode 6 can be controlled through a gate wiring 14.

Electrons generated by the zener breakdown are trapped in the surface oxide film 2, which causes a charge up phenomenon causing the shift of the zener voltage, when the zener junction is formed near the surface of the silicon substrate 1. In the zener diode 100, the change up phenomenon is prevented by forming the gate electrode 6 over the zener junction. Namely, in the zener diode 100, the electrons stored in the surface oxide film 2 are disappeared by supplying certain positive voltage to the gate electrode 6, so that the charge up phenomenon can be prevented. Hereby, the shift of the zener voltage caused by the charge up phenomenon can be prevented.

Also, the zener voltage can be controlled by changing the voltage supplied to the gate electrode 6. Namely, a depletion layer extends from the surface of the silicon substrate 1 into the p⁺ anode region 5, when positive voltage is supplied to the gate electrode 6. Hereby, the zener breakdown, which determines the zener voltage of the zener diode 100, is hardly generated at the zener junction near the surface of the silicon substrate 1.

On the contrary, the depletion layer extending into the p⁺ anode region 5 becomes thinner, when negative voltage is supplied to the gate electrode 6. Hereby, the zener breakdown is easily generated.

FIG. 2 shows a relation between the gate voltage and the zener voltage in the zener diode 100. A horizontal axis shows the gate voltage supplied to the gate electrode 6, and a vertical axis shows the zener voltage of the zener diode 100.

As shown in FIG. 2, the zener voltage decreases when the positive voltage is supplied to the gate electrode 6, on the other hand, the zener voltage increases when the negative voltage is supplied to the gate electrode 6. Consequently, in the zener diode 100, the zener voltage can be controlled by changing the voltage supplied to the gate electrode 6.

FIG. 3 shows an example of a control circuit diagram for controlling the zener voltage by using the gate voltage in the zener diode 100. A controller is connected to the zener diode in parallel between the A (anode) and K (cathode) terminals. In the controller, the voltage (zener voltage) between A (anode) and K (cathode) terminals is monitored, and the voltage of G (gate) terminal is controlled according to the monitored voltage. By using the control circuit for the zener diode 100, the gate voltage can be changed with monitoring the zener voltage. Hereby, the zener voltage can be maintained at a desired value.

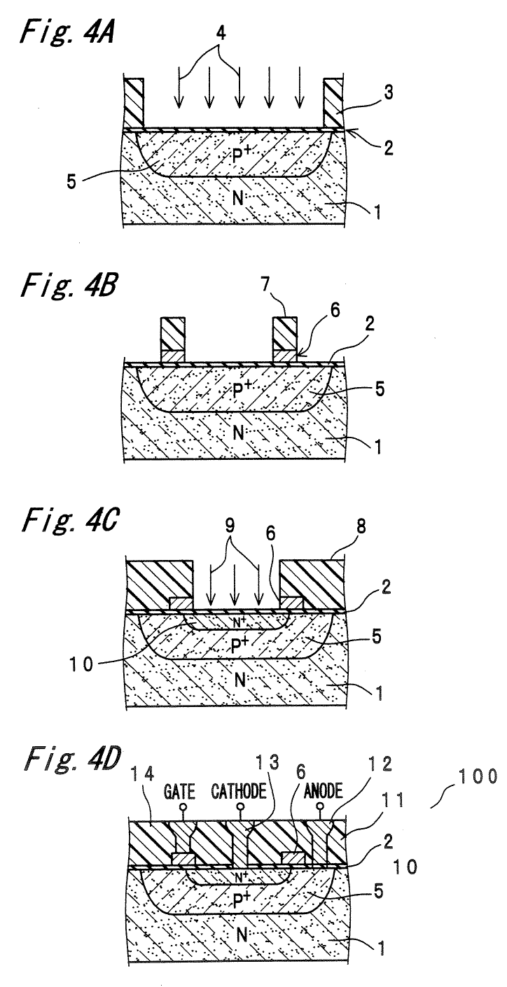

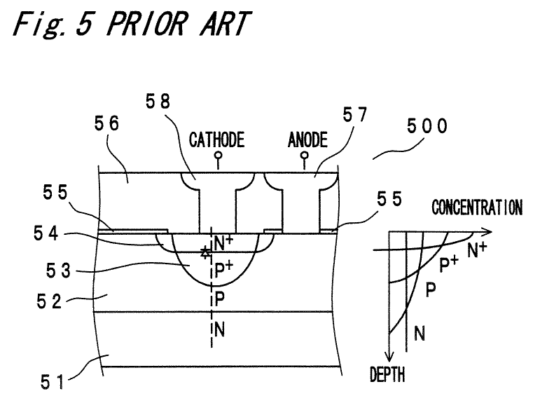

Next, a method of producing the zener diode 100 according to this embodiment will now be described with reference to FIGS. 4A to 4D. The method includes the following steps 1 to 4.

Step 1: As shown in FIG. 4A, the n-type silicon substrate 1 is prepared. A silicon substrate having an n-type well region may be used. Then, the surface oxide film 2 of oxide silicon is formed on the surface of the silicon substrate 1 by using a thermal oxide method for instance.

Next, a resist mask 3 is formed, and then a p-type ion 4 of boron (B) or the like is injected into the silicon substrate 1 by using the resist mask 3 as an implantation mask. The implantation energy of the p-type ion 4 is in the range of 10 to 30 KeV for instance, and its dose amount is in the range of 1×10¹⁴ to 11×10 cm⁻² for instance. An annealing step can be applied after the ion implantation step, if needed.

The ion implantation under the above condition makes it possible to form the p⁺ anode region 5 in which the concentration of the impurity becomes highest near the surface of the silicon substrate 1 and progressively decreases toward the depth direction.

Step 2: As shown in FIG. 4B, a poly-silicon layer is formed on the surface oxide film 2 by using a CVD method for instance. Then the poly-silicon layer is patterned by using a resist mask 7. Consequently, the gate electrode 6 of poly-silicon is formed on the p⁺ anode region 5.

Step 3: As shown in FIG. 4C, a resist mask 8 is formed to cover the gate electrode 6 and its outer portion, and then an n-type ion 9 of arsenic (As) or the like is injected into the p⁺ anode region 5 by using the resist mask 8 as an implantation mask. The implantation energy of the n-type ion 9 is in the range of 10 to 30 KeV for instance, and its dose amount is in the range of 1×10¹⁵ to 1×10¹⁶ cm⁻² for instance. An annealing step can be applied after the ion implantation step, if needed.

The ion implantation under the above condition makes it possible to form the n⁺ cathode region 10 in which the concentration of the impurity becomes highest near the surface of the silicon substrate 1 (p⁺ anode region 5) and progressively decreases toward the depth direction. It should be noted that the n⁺ region 10 is included in the p⁺ anode region 5.

Step 4: As shown in FIG. 4D, the interlayer insulating film 11 of oxide silicon or the like is formed by using a CVD method. The thickness of the interlayer insulating film 11 is in the range of 3000 to 10000 Angstrom for instance. Finally, apertures are formed in the interlayer insulating film 11, and the anode wiring 12 connected to the p⁺ anode region 5, the cathode wiring 13 connected to the n⁺ cathode region 10, and the gate wiring 14 connected to the gate electrode 6 are formed in the apertures. The anode wiring 12, the cathode wiring 13, and the gate wiring 14 are formed by using an aluminum evaporation method for instance. It should be noted that the surface protection film of BPSG or the like (not shown) may be formed on the interlayer insulating film 11, if needed.

Through these steps, the zener diode 100 according to this embodiment is completed.

What is claimed is:

1. A zener diode, comprising:
a semiconductor substrate;
a first region of the first conductivity type formed on the surface of the semiconductor substrate; and
a second region of the second conductivity type formed on the surface of the semiconductor substrate and included in the first region;
and having a pn junction between the first and the second regions;
wherein the concentration of the impurity of the first conductivity type in the first region is highest near the surface of the semiconductor substrate, and the concentration of the impurity of the second conductivity type in the second region is highest near the surface of the semiconductor substrate.

2. The zener diode according to claim 1, wherein an insulating film is formed on the surface of the semiconductor substrate, and further comprising a gate electrode opposing to the edge of the pn junction exposed to the surface through the insulating film.

3. The zener diode according to claim 2, wherein positive voltage is supplied to the gate electrode.

4. The zener diode according to claim 2, wherein the breakdown voltage of the pn junction is controlled by changing the voltage supplied to the gate electrode.
